(19) United States
(12) Patent Application Publication
(10) Pub. No.: US 2015/0263018 A1
(43) Pub. Date: Sep. 17, 2015

(54) SEMICONDUCTOR DEVICE AND METHOD OF MANUFACTURING THE SAME

(71) Applicant: KABUSHIKI KAISHA TOSHIBA, Minato-ku (JP)

(72) Inventor: Akihito IKEDO, Yokkaichi (JP)

(73) Assignee: KABUSHIKI KAISHA TOSHIBA, Minato-ku (JP)

(21) Appl. No.: 14/484,493

(22) Filed: Sep. 12, 2014

Related U.S. Application Data
(60) Provisional application No. 61/951,357, filed on Mar. 11, 2014.

(51) Int. Cl. H01L 27/115; H01L 29/06; H01L 29/49; H01L 21/28; H01L 29/66; H01L 21/762; H01L 21/311; H01L 21/285; H01L 29/788; H01L 29/51

(52) U.S. Cl. CPC H01L 27/11524; H01L 29/788; H01L 29/0649; H01L 29/4925; H01L 29/518; H01L 29/517; H01L 29/66825; H01L 27/11529; H01L 21/76224; H01L 21/31111; H01L 21/2855; H01L 29/513; H01L 29/495; H01L 21/28273

(57) ABSTRACT

A semiconductor device including a semiconductor substrate having an active region and an element isolation region; memory-cell transistors and select-gate transistors each formed above the substrate and having a gate electrode formed above the active region via a first insulating film, the gate electrode including a floating gate electrode, an interelectrode insulating film, and a control gate electrode; the element isolation region being formed of a trench and an insulating film filled in the trench, a position of an upper surface of the insulating film located between the gate electrodes of the memory cell transistors being higher than a position of the upper surface of the floating gate electrode, and a position of an upper surface of the insulating film located between the gate electrodes of the select-gate transistors being lower than a position of the upper surface of the floating gate electrode.

### CROSS-REFERENCE TO RELATED APPLICATION(S)

This application is based upon and claims the benefit of priority from U.S. Provisional Patent Application No. 61/951,357, filed on, Mar. 11, 2014 the entire contents of which are incorporated herein by reference.

### FIELD

Embodiments disclosed herein relate to a semiconductor device and a method of manufacturing the same.

### BACKGROUND

Microfabrication of NAND flash memory devices is in progress to achieve larger storage capacity. As a result of microfabrication, a NAND flash memory device having a rocket-type cell structure is being manufactured in which the gate electrode of the memory-cell transistor is shaped like a rocket. In a device employing a rocket-type cell structure, processing of the features may become difficult as the aspect ratio increases or a gap fill error may occur during the formation of a control gate electrode. Development of flat-cell NAND flash memory device is expected to address such concerns.

In a flat-cell device, the thickness of a floating gate electrode is reduced. Thus, it becomes difficult to electrically connect the floating gate electrode and the control gate electrode in a gate electrode of the select gate transistor. This results in reduced gate capacitance and therefore degrades the properties of the select-gate transistor as compared to the rocket-cell device. The amount of etch back of the element isolation insulating film may be increased in order to increase the gate capacitance. However, because the memory-cell transistor and the select-gate transistor are etched back at the same time, too much increase in the amount of etch back may reduce the breakdown voltage between the control gate electrode and the active region of the silicon substrate.

### BRIEF DESCRIPTION OF THE DRAWINGS

FIG. 1 pertains to a first embodiment and is one example of an equivalent circuit diagram partially illustrating a memory cell array of a NAND flash memory device.

FIG. 2 is one schematic example of a plan view partially illustrating a layout pattern of a memory cell region.

FIG. 3A is one schematic example of a cross sectional view taken along line A-A of FIG. 2, and FIG. 3B is one schematic example of a cross sectional view taken along line B-B of FIG. 2.

FIG. 4A is one schematic example of a cross sectional view taken along line C-C of FIG. 2, and FIG. 4B is one schematic example of a cross sectional view taken along line D-D of FIG. 2.

FIG. 5 is one example of a cross sectional view taken along line A-A of FIG. 2 at one phase of a manufacturing process flow.

FIG. 6 is one example of a cross sectional view taken along line A-A of FIG. 2 at one phase of the manufacturing process flow.

FIG. 7 is one example of a cross sectional view taken along line A-A of FIG. 2 at one phase of the manufacturing process flow.

FIG. 8 is one example of a cross sectional view taken along line A-A of FIG. 2 at one phase of the manufacturing process flow.

FIG. 9 is one example of a cross sectional view taken along line A-A of FIG. 2 at one phase of the manufacturing process flow.

FIG. 10 is one example of a cross sectional view taken along line A-A of FIG. 2 at one phase of the manufacturing process flow.

FIG. 11 is one example of a cross sectional view taken along line A-A of FIG. 2 at one phase of the manufacturing process flow.

FIG. 12 is one example of a cross sectional view taken along line A-A of FIG. 2 at one phase of the manufacturing process flow.

FIG. 13A is one example of a cross sectional view taken along line A-A of FIG. 2 at one phase of the manufacturing process flow and

FIG. 13B is one example of a cross sectional view taken along line B-B of FIG. 2 at one phase of the manufacturing process flow.

FIG. 14A is one example of a cross sectional view taken along line A-A of FIG. 2 at one phase of the manufacturing process flow and

FIG. 14B is one example of a cross sectional view taken along line B-B of FIG. 2 at one phase of the manufacturing process flow.

FIG. 15A is one example of a cross sectional view taken along line A-A of FIG. 2 at one phase of the manufacturing process flow and

FIG. 15B is one example of a cross sectional view taken along line B-B of FIG. 2 at one phase of the manufacturing process flow.

FIG. 16A is one example of a cross sectional view taken along line A-A of FIG. 2 at one phase of the manufacturing process flow and

FIG. 16B is one example of a cross sectional view taken along line B-B of FIG. 2 at one phase of the manufacturing process flow.

FIG. 17A is one example of a cross sectional view taken along line A-A of FIG. 2 at one phase of the manufacturing process flow and

FIG. 17B is one example of a cross sectional view taken along line B-B of FIG. 2 at one phase of the manufacturing process flow.

FIG. 18 corresponds to FIG. 2.

FIG. 19 pertains to a second embodiment and corresponds to FIG. 2.

FIG. 20 is one example of a cross sectional view taken along line E-E of FIG. 19.

FIG. 21 pertains to a third embodiment and corresponds to FIG. 2.

FIG. 22 is one example of a cross sectional view taken along line F-F of FIG. 21.

FIG. 23 pertains to a fourth embodiment and corresponds to FIG. 3A.

FIG. 24 pertains to a fifth embodiment and corresponds to FIG. 3B.

### DETAILED DESCRIPTION

In one embodiment, a semiconductor device includes a semiconductor substrate having an active region and an element isolation region, the active region being isolated by the element isolation region; memory-cell transistors each being formed above the semiconductor substrate and having a gate electrode formed above the active region via a first insulating film, the gate electrode being formed of a stack including a floating gate electrode, an interelectrode insulating film, and a control gate electrode; and select-gate transistors each being formed above the semiconductor substrate and having a gate electrode formed above the active region via the first insulating film, the gate electrode being formed of a stack including a floating gate electrode, an interelectrode insulating film, and a control gate electrode. The element isolation region is formed of an element isolation trench and an element isolation insulating film filled in the element isolation trench. A position of an upper surface of the element isolation insulating film located between the gate electrodes of the memory cell transistors is higher than a position of the upper surface of the floating gate electrode. A position of an upper surface of the element isolation insulating film located between the gate electrodes of the select-gate transistors is lower than a position of the upper surface of the floating gate electrode.

Embodiments are described hereinafter with reference to the drawings. In each of the embodiments, elements that are substantially identical are identified with identical reference symbols and are not re-described. However, the drawings are schematic and thus, do not reflect the actual measurements of the features such as the correlation of thickness to planar dimensions and the ratio of thicknesses of each of the layers.

### First Embodiment

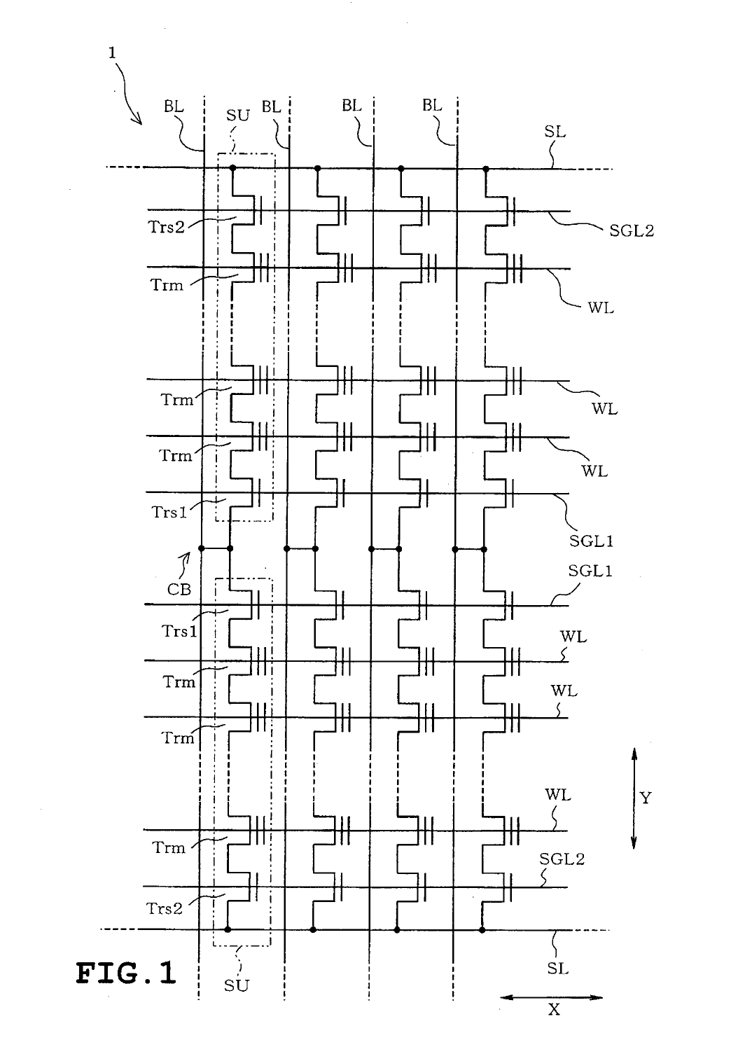

Referring first to FIG. 1, an equivalent circuit diagram is provided which partially illustrates a memory-cell array formed in a memory-cell region of a NAND flash memory device of a first embodiment. As illustrated in FIG. 1, the memory cell array of the NAND flash memory device is configured by NAND cell units SU arranged in rows and columns. NAND cell unit SU is configured by a couple of select-gate transistors Trs1 and Trs2 and series connected memory-cell transistors Trm (such as 32 in number) connected between the couple of select-gate transistors Trs1 and Trs2. The adjacent memory-cell transistors Trm within NAND cell unit SU share their source/drain regions.

Memory-cell transistors Trm aligned in the X direction (corresponding to word line direction, gate width direction) as viewed in FIG. 1 are interconnected by a common word line WL. Select-gate transistors Trs1 aligned in the X direction as viewed in FIG. 1 are interconnected by a common select-gate line SGL1 and select-gate transistors Trs2 are interconnected by a common select-gate line SGL2. The drain of select-gate transistor Trs1 is connected to bit line contact CB. Bit line contact CB is connected to bit line BL extending in the Y direction (corresponding to gate length direction, bit line direction) orthogonal to the X direction as viewed in FIG. 1. Select-gate transistor Trs2 is connected to source line SL extending in the X-direction as viewed in FIG. 1 via a source region.

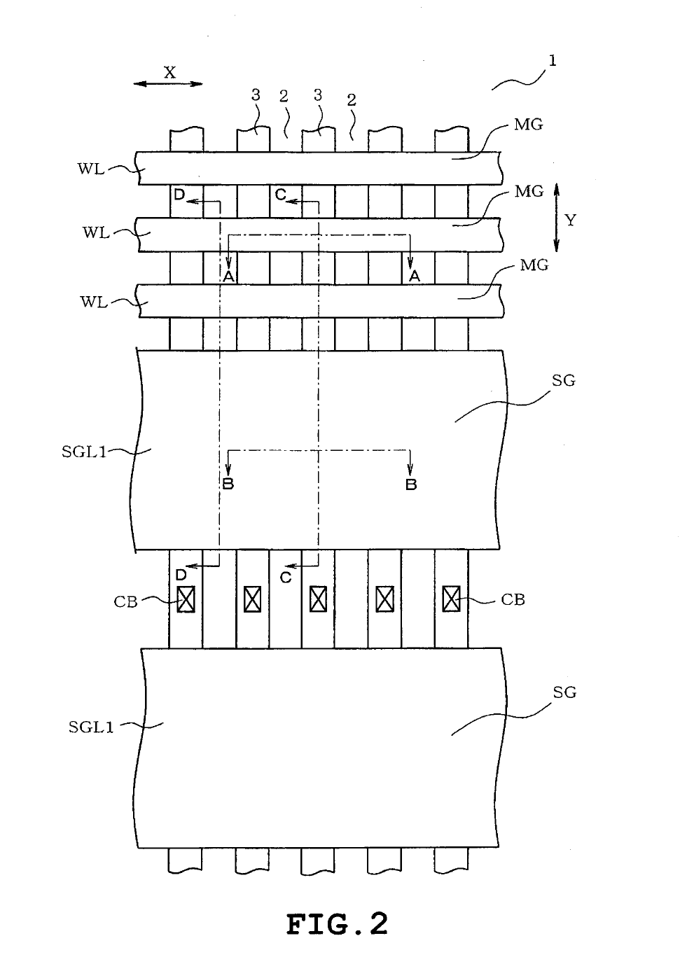

FIG. 2 is a plan view partially illustrating a layout pattern of the memory cell region. STIs 2 serving as element isolation regions extend along the Y direction in silicon substrate 1 serving as a semiconductor substrate. STIs 2 are spaced from one another by a predetermined spacing in the X direction as viewed in FIG. 2. As a result, active regions 3, extending in the Y-direction as viewed in FIG. 2, are isolated in the X direction as viewed in FIG. 2. Word lines WL of memory-cell transistors Trm are formed so as to extend in the direction orthogonal to active region 3 (the X direction as viewed in FIG. 2) and are spaced from one another in the Y direction as viewed in FIG. 2 by a predetermined spacing.

Further, pairs of select-gate lines SGL1 of the select-gate transistors are formed so as to extend along the X direction as viewed in FIG. 2. In each active region 3 located between the pairs of select-gate lines SGL1, bit line contact CB is formed. Above active region 3 intersecting with word line WL, gate electrode MG of the memory-cell transistor is formed. Above active region 3 intersecting with select-gate line SGL1, gate electrode SG of select-gate transistor is formed.

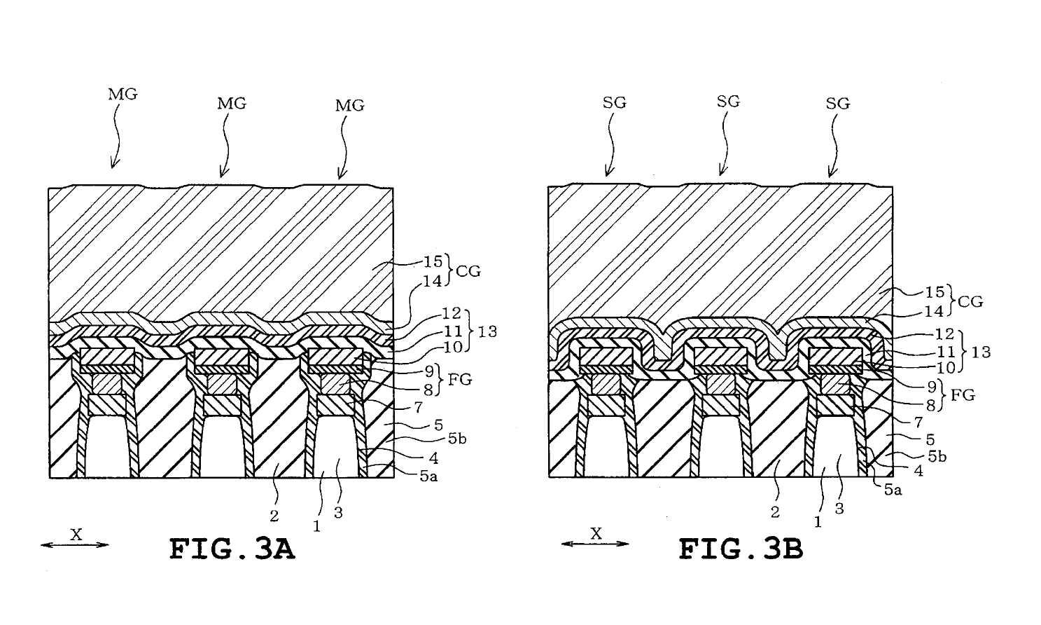

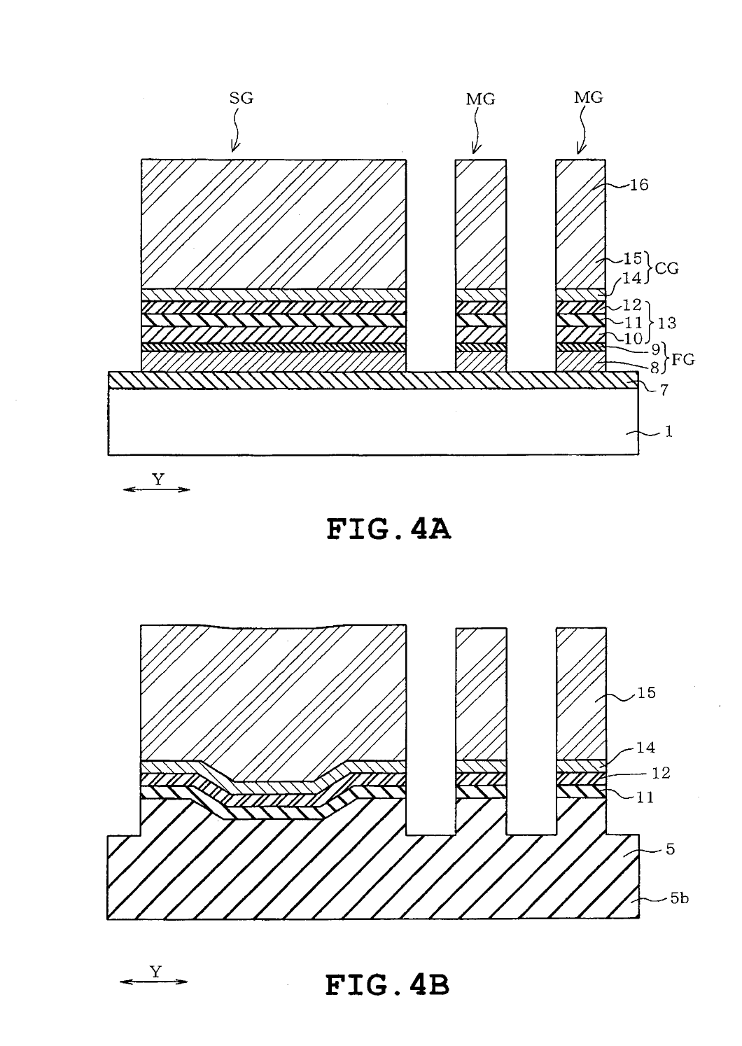

Referring to FIGS. 3A, 3B, 4A and 4B, a description will be given on flat-cell gate electrodes provided in the memory-cell region of the present embodiment. FIG. 3A is one example of a view schematically illustrating a cross section taken along line A-A (word line direction, X direction) of FIG. 2. FIG. 3B is one example of a view schematically illustrating a cross section taken along line B-B (word line direction, X direction) of FIG. 2. FIG. 4A is one example of a view schematically illustrating a cross section taken along line C-C (bit line direction, Y direction) of FIG. 2. FIG. 4B is one example of a view schematically illustrating a cross section taken along line D-D (bit line direction, Y direction) of FIG. 2.

Referring to FIGS. 3A, 3B, 4A, and 4B, element isolation trenches 4 are formed in an upper portion of silicon substrate 1 so as to be spaced from one another in the X direction. Element isolation trenches 4 isolate active region 3 in the X direction as viewed in FIGS. 3A and 3B. Element isolation insulating films 5 are formed in element isolation trenches 4 to form element isolation regions (STI) 2. Element isolation insulating film 5 comes in the form of sidewall insulating film 5a and gap fill insulating film 5b.

Gate electrode MG of the memory-cell transistor is disposed above tunnel insulating film (gate insulating film) 7 formed above silicon substrate 1 (active region 3 of silicon substrate 1). Tunnel insulating film 7 is formed of for example a silicon oxide (SiO₂). Tunnel insulating film 7 is normally insulative, but allows flow of tunnel current when a voltage of a predetermined level within the drive voltage of the NAND flash memory device is applied. Source/drain region (not shown) is formed in the surface layer portion of silicon substrate 1 so as to be located in both sides of gate electrode MG.

Above tunnel insulating film 7, silicon film 8 formed of a polycrystalline silicon is formed. Above silicon film 8, insulating film (IFD film) 9 formed of a silicon nitride (SiN) for example is formed. Above insulating film 9, first block film 10 formed of hafnium oxide (HfSiO) for example is formed. Floating gate electrode film FG is configured by silicon film 8 and insulating film 9.

Floating gate electrode films FG are formed above silicon substrate 1 and are arranged in a matrix along the X direction and the Y direction. Between the stacks each formed of floating gate electrode film FG and first block film 10, the upper portion of element isolation insulating film 5 is disposed.

Above first block film 10 and element isolation insulating film 5, second block film 11 formed of a silicon oxide (SiO₂) for example and third oxide film 12 formed of hafnium oxide (HfSiO) for example are formed in the listed sequence. Second block film 11 and third block film 12 extend in the X direction. IPD (inter poly dielectric) film (interelectrode film) 13 is formed by first block film 10, second block film 11, and third block film 12.

Above IPD film 13, an electrically conductive barrier film 14 formed of tungsten nitride (WN) for example is formed. Above barrier film 14, conductive film 15 formed of tungsten (W) for example is formed. Control gate electrode CG extending in the X direction is formed by barrier film 14 and conductive film 15.

In the above described structure, gate stack 16 extending in the X direction is formed by the upper portion of element isolation insulating film 5, tunnel insulating film 7, floating gate electrode FG, IPD film 13, and control gate electrode CG. More than one gate stacks 16 are provided above silicon substrate 1. An interlayer insulating film (not shown) formed of a silicon oxide for example is formed between and above gate stacks 16. Above the interlayer insulating film, upper layer wirings (not shown) including bit lines are formed.

The structure of the stack of gate electrode SG of the select-gate transistor is substantially identical to the structure of the stack of gate electrode MG of the memory-cell transistor. The differences are described below. In the memory-cell transistor, the position of the upper portion of element isolation insulating film 5 is substantially in the same position with or slightly in a lower position than the position of the upper portion of first block film 10 as illustrated in FIG. 3A. In contrast, in the select-gate transistor, the position of the upper portion of element isolation insulating film 5 is in a lower position (a position located substantially in the middle of the thickness direction of silicon film 8) than the upper portion of silicon film 8 as illustrated in FIG. 3B. That is, as shown in FIG. 4B, the position of the upper portion of element isolation insulating film 5 of the select-gate transistor portion is lower than the position of the upper portion of element isolation insulating film 5 of the memory-cell transistor portion.

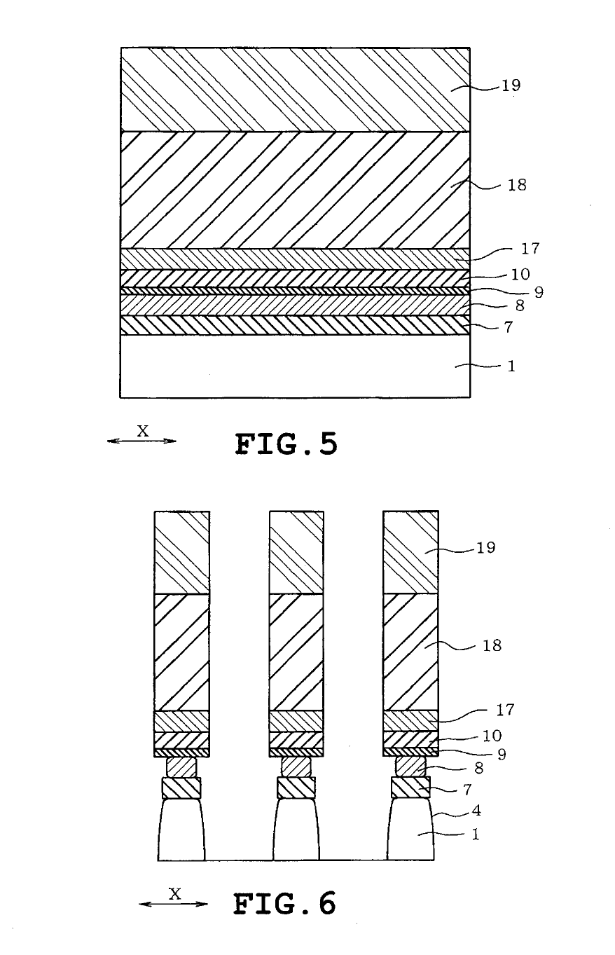

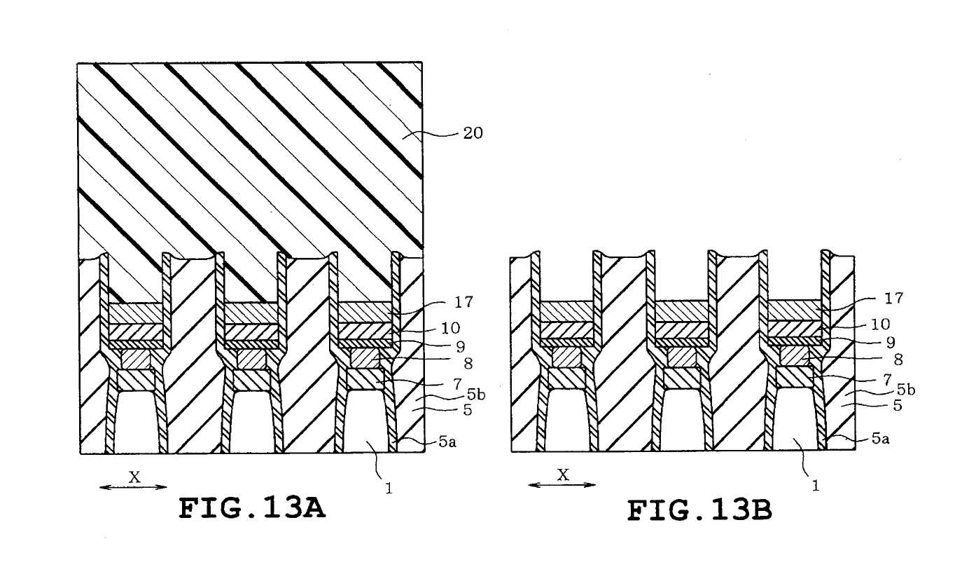

Next, a description is given on one example of a manufacturing method of the NAND flash memory device of the present embodiment with reference to FIGS. 5 to 17. FIGS. 5 to 12 and 13A to 17A schematically illustrate one phase of the manufacturing process flow of the cross sectional structure corresponding to FIG. 3A. FIGS. 13B to 17B schematically illustrate one phase of the manufacturing process flow of the cross sectional structure corresponding to FIG. 3B.

First, as shown in FIG. 5, tunnel insulating film 7 formed of a silicon oxide for example is formed above silicon substrate 1. Then, silicon film 8 formed of a polycrystalline silicon is formed above tunnel insulating film 7. Then, insulating film 9 formed of a silicon nitride 9 is formed above silicon film 8. Then, first block film 10 formed of hafnium oxide (HfSiO) for example is formed above insulating film 9.

Thereafter, cover film 17 formed of a silicon oxide for example is formed above first block film 10. Then, above cover film 17, silicon nitride film 18 formed of a silicon nitride for example is formed which serves as a later described CMP stopper film. Subsequently, above silicon nitride film 18, silicon oxide film 19 formed of a silicon oxide for example is formed which serves as a hard mask.

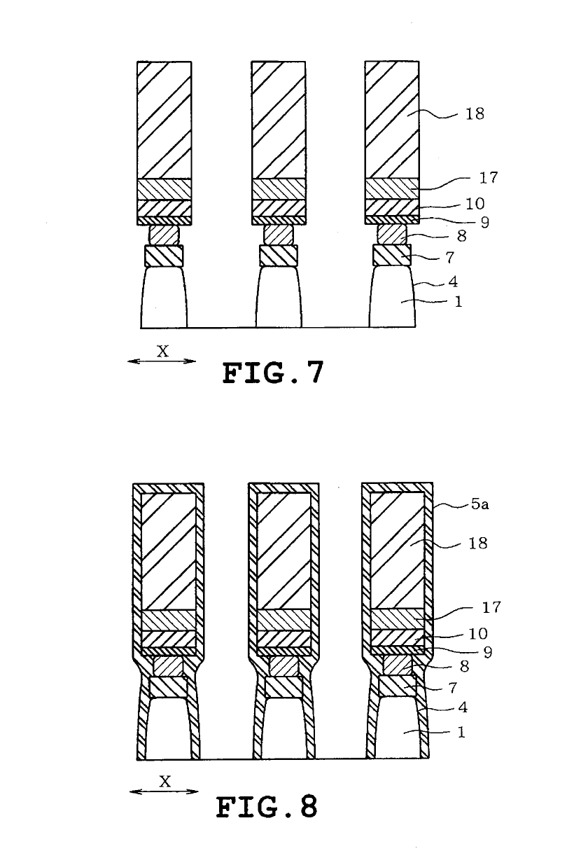

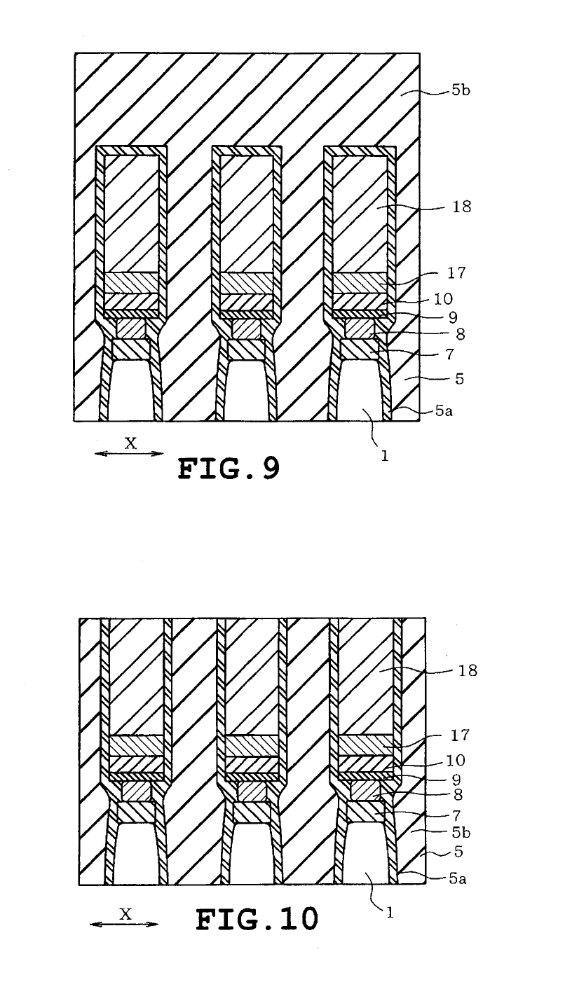

Next, element isolation trenches 4 are formed by etching silicon oxide film 19, silicon nitride film 18, cover film 17, first block film 10, insulating film 9, silicon film 8, tunnel insulating film 7, and silicon substrate 1 using photolithography (which may include sidewall transfer process) for example and RIE (reactive ion etching) for example. As a result, it is possible to obtain the structure illustrated in FIG. 6. Then, silicon oxide film 19 is removed as illustrated in FIG. 7. Next, sidewall insulating film 5a formed of a silicon oxide for example is formed across the entire surface as illustrated in FIG. 8. Subsequently, silicon oxide film (gap fill insulating film) 5b formed of a polysilazane (PSZ) for example is formed along sidewall insulating film 5a using a coating technique for example as illustrated in FIG. 9.

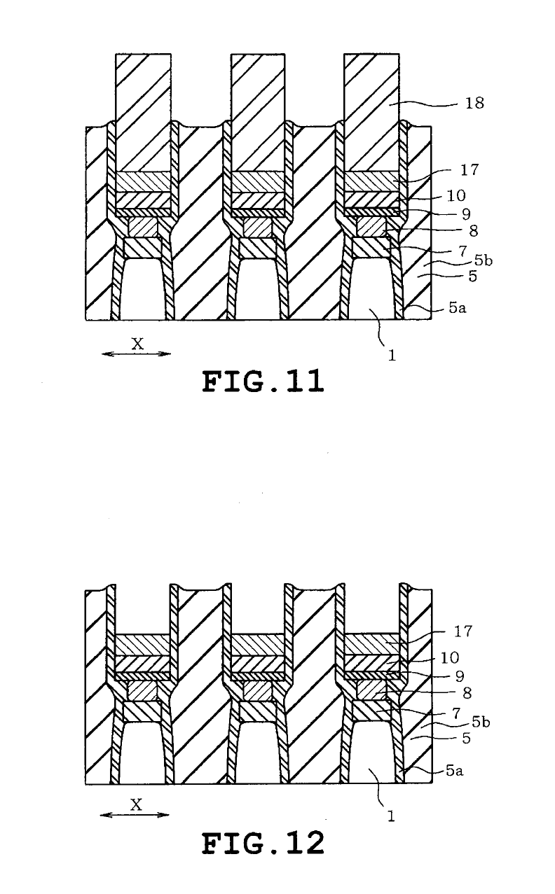

Then, as illustrated in FIG. 10, planarization is carried out using CMP (chemical mechanical polishing) for example until the upper surface of silicon nitride film 18 is exposed. Subsequently, gap fill insulating film 5b and sidewall insulating film 5a, in other words, element isolation insulating film 5 is etched back by wet etching for example as illustrated in FIG. 11. Thereafter, silicon nitride film 18 is removed by wet etching for example as illustrated in FIG. 12.

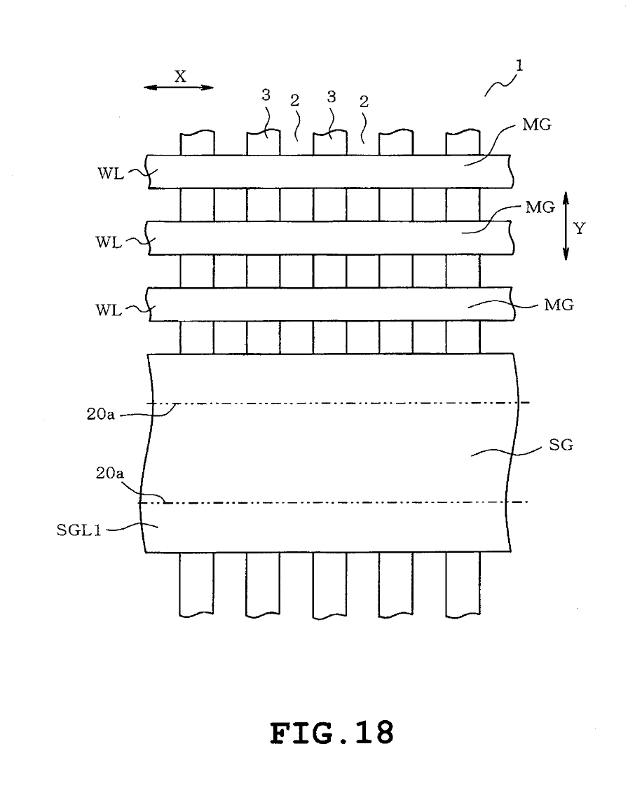

Then, as illustrated in FIGS. 13A and 13B, photoresist 20 is coated across the entire surface and the resist is patterned by exposure and development to form an opening only in gate electrode SG portion of the select-gate transistor. As indicated by double-dot chain line in FIG. 18 for example, opening 20a of resist 20 is formed so as to extend in the X direction in the portion corresponding to the Y-direction mid portion select-gate line SGL(SGL2) of select-gate transistor Trs1 (Trs2). In this example, the area of opening 20a is substantially half the area of select-gate line SGL1 (SGL2).

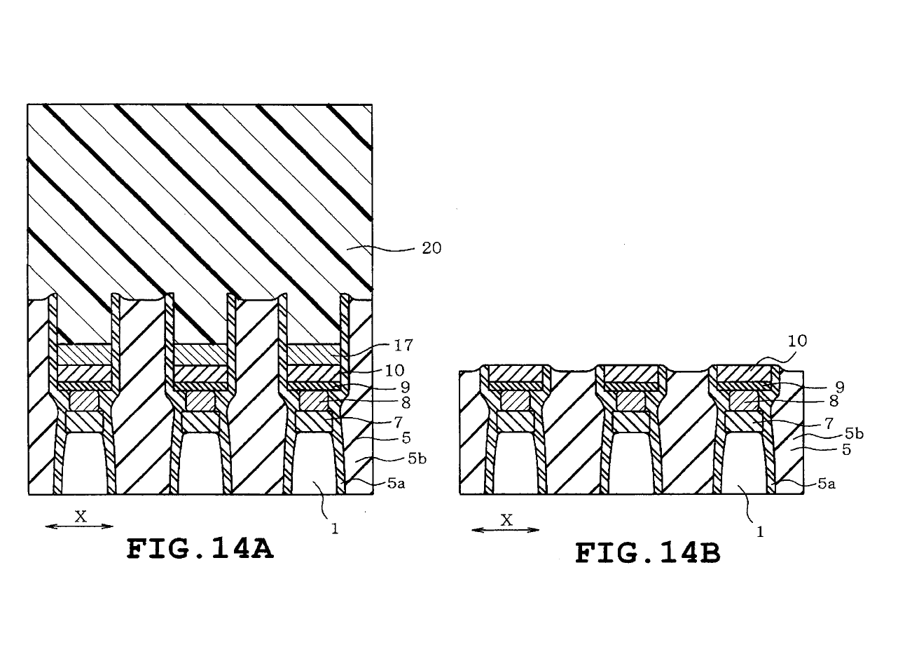

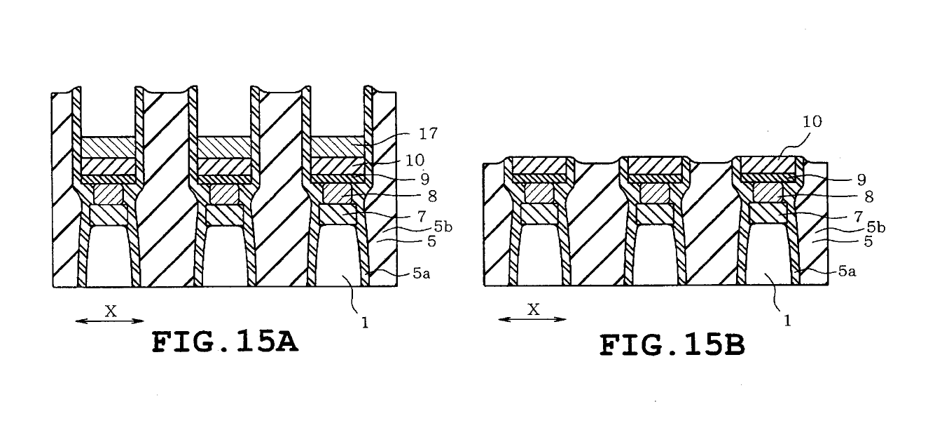

Next, as illustrated in FIG. 14B, resist 20 having opening 20a patterned thereto is used as a mask to etch element isolation insulating film 5 of select-gate line SGL portion of the select-gate transistor and cover film 17 by wet etching for example. The etching removes cover film 17 and also renders the position of the upper portion of element isolation insulating film 5 to be lower than the position of the upper surface of first block film 10. Then, resist 20 is removed as illustrated in FIG. 15A.

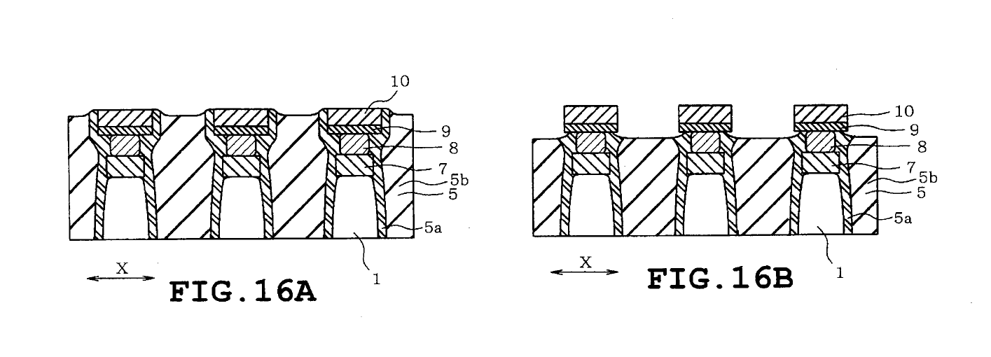

Thereafter, as illustrated in FIGS. 16A and 16B, element isolation insulating film 5 and cover film 17 are etched by wet etching for example. As a result, cover film 17 is removed and the position of the upper portion of element isolation insulating film 5 of word line WL portion of the memory-cell transistor is substantially in the same position with or slightly in a lower position than the position of the upper portion of first block film 10 while the position of the upper portion of element isolation insulating film 5 of select-gate line SGL portion of the select-gate transistor is in a lower position (a position located substantially in the middle of the thickness direction of silicon film 8) than the upper portion of silicon film 8. Element isolation insulating film 5 is formed as the result of this etch back. The lower portion of element isolation insulating film 5 fills element isolation trench 4. The upper portion of element isolation insulating film 5 is disposed between the stacks each formed of tunnel insulating film 7, silicon film 8, insulating film 9, and first block film 10 in the memory-cell transistor portion, whereas in the select-gate transistor portion, between the stacks each formed of tunnel insulating film 7 and silicon film 8.

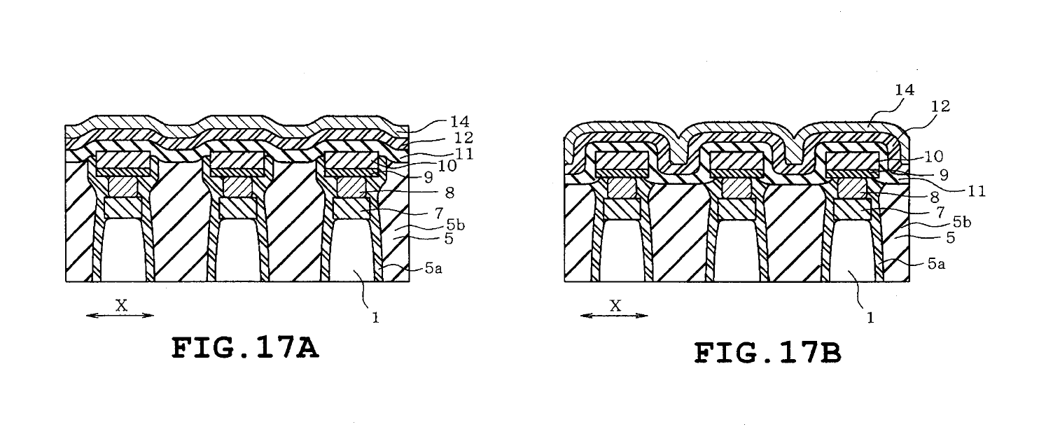

Then, as illustrated in FIG. 17, second block film 11 formed of a silicon oxide (SiO₂) is formed across the entire surface (above first block film 10 and element isolation insulating film 5). Then, above second block film 11, third block film 12 formed of hafnium oxide (HfSiO) for example is formed. Thereafter, above third block film 12, barrier film 14 formed of tungsten nitride (WN) for example is formed. Subsequently, above barrier film 14, conductive film 15 formed of tungsten (W) for example is formed by sputtering as illustrated in FIGS. 3A and 3B.

Thereafter, a line-and-space patterned hard mask (not shown) is formed so as to extend in the X direction. Then, anisotropic etching is performed using the hard mask as a mask to selectively remove conductive film 15, barrier film 14, third block film 12, second block film 11, first block film 10, insulating film 9, silicon film 8, and the upper portion of element isolation insulating film 5 (refer to FIGS. 4A and 4B). As a result, gate stacks 16 extending in the X direction are formed.

In the above described structure, the stacks formed of silicon film 8 and insulating film 9 are isolated along the X direction and the Y direction and serve as floating gate electrodes FG aligned in a matrix. Further, the stack formed of first block film 10, second block film 11, and third block film 12 serve as IPD film 13. Further, the stacks each being formed of barrier film 14 and conductive film 15 are shaped into stripes extending in the X direction and serve as control gate electrodes CG.

Next, a silicon oxide film for example is deposited across the entire surface and thereafter planarized to form an interlayer insulating film (not shown) between and above gate stacks 16. Then, upper-layer wirings (not shown) including bit lines are formed above the interlayer insulating film.

In the present embodiment structured as described above, the position of the upper surface of element isolation insulating film 5 located between the gate electrodes of the memory-cell transistors are configured to be located higher than the position of the upper surface of floating gate electrode FG, while the position of the upper surface of element isolation insulating film 5 located between the gate electrodes of the select-gate transistors are configured to be located at the vertical mid portion of floating gate electrode FG. In the above described structure, it is possible to improve the cut-of f properties of the select-gate transistor since the gate capacitance of the gate electrode of the select-gate transistor can be increased without reducing the breakdown voltage of the memory-cell transistor.

### Second Embodiment

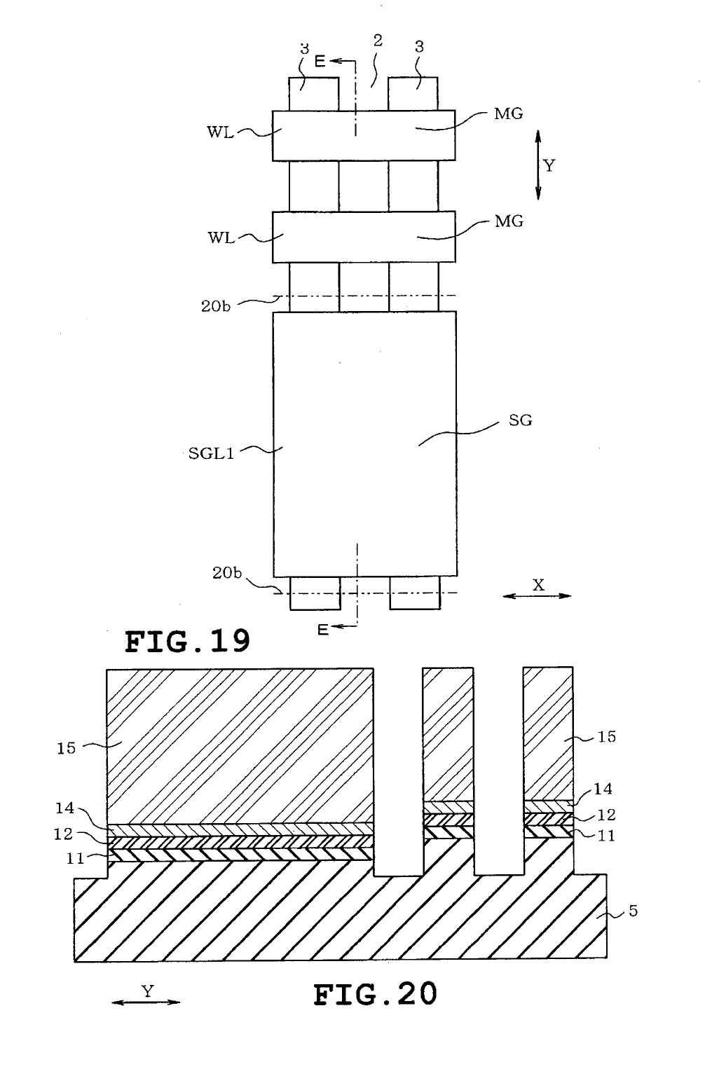

FIGS. 19 and 20 illustrate a second embodiment. Structures identical to the first embodiment are identified with identical reference symbols. In the second embodiment, substantially the entire region of select-gate lines SGL1 (SGL2) portion is subjected to the lowering of the position of the upper portion of element isolation insulating film 5 of the select-gate transistor portion.

More specifically, in the step illustrated in FIGS. 13A and 13B of the first embodiment, photoresist 20 is coated above the entire surface and the resist is patterned by exposure and development to form an opening only in gate electrode SG portion of the select gate transistor. At this instance, opening 20b of resist 20 is formed as indicated by double-dot chain line in FIG. 19. That is, opening 20b described above is defined to entirely encompass select-gate line SGL1 (SGL2) of select-gate transistor Trs1 (Trs2). Opening 20b is formed so as to extend in the X direction. The area of opening 20b is substantially equal to or slightly larger than the area of select-gate line SGL1 (SGL2).

Then, using resist 20 in which the above described opening 20b is patterned, element isolation insulating film 5 and cover film 17 of select-gate line SGL portion of the select-gate transistor is etched by wet etching for example as was the case in the first embodiment. The etching removes cover film 17 and lowers the position of the upper portion of element isolation insulating film 5 so as to be, for example, lower than the position of the upper surface of first block film 10. The subsequent steps may follow the steps similar to those of the first embodiment.

FIG. 20 schematically illustrates the cross section taken along line E-E of FIG. 19. As illustrated in FIG. 20, the position of the upper portion of element isolation insulating film 5 of the select-gate transistor portion is lowered throughout the portion corresponding to the entire Y-direction length of select-gate lines SGL1 (SGL2).

Apart from those described above, the structures of the second embodiment are the same as the structures of the first embodiment. Thus, it is possible to obtain the operation and effect substantially identical to those of the first embodiment in the second embodiment as well. Especially in the second embodiment, the position of the upper portion of element isolation insulating film 5 is lowered throughout the portion corresponding to the entire Y-direction length of select-gate lines SGL1 (SGL2). As a result, it is possible to improve the properties of the select-gate transistors even more effectively.

### Third Embodiment

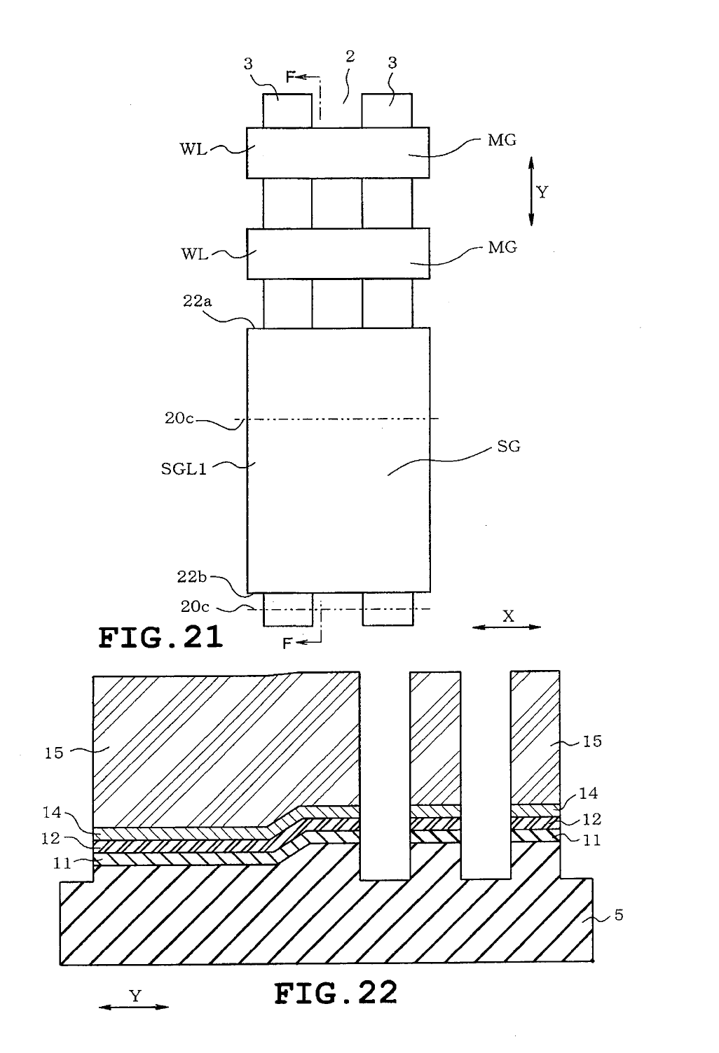

FIGS. 21 and 22 illustrate a third embodiment. Structures identical to the first embodiment are identified with identical reference symbols. In the third embodiment, a portion of select-gate lines SGL1 (SGL2) located in the opposite side of the portion located adjacent to the memory-cell transistor is subjected to the lowering of the position of the upper portion of element isolation insulating film 5 of the select-gate transistor portion.

More specifically, in the step illustrated in FIGS. 13A and 13B of the first embodiment, photoresist 20 is coated above the entire surface and the resist is patterned by exposure and development to form an opening only in gate electrode SG portion of the select gate transistor. At this instance, opening 20c of resist 20 is formed as indicated by double-dot chain line in FIG. 21. That is, opening 20c described above is defined from the position in the inner side of the Y-direction edge 22a of select-gate line SGL1 (SGL2) of select-gate transistor Trs1 (Trs2) to the position in the outer side of the Y-direction edge 22b in the opposite side of the memory cell of select-gate line SGL1 (SGL2). Opening 20c is formed so as to extend in the X direction. The area of opening 20c is substantially equal to or slightly less than the area of select-gate line SGL1 (SGL2).

FIG. 22 schematically illustrates the cross section taken along line F-F of FIG. 21. As illustrated in FIG. 22, the position of the upper portion of element isolation insulating film 5 of the select-gate transistor portion is lowered except for the portion located near the memory-cell side edge among the entire Y-direction length of select-gate line SGL1 (SGL2) of the select-gate transistor.

Apart from those described above, the structures of the third embodiment are the same as the structures of the first embodiment. Thus, it is possible to obtain the operation and effect substantially identical to those of the first embodiment in the third embodiment as well. Especially in the third embodiment, the position of the upper portion of element isolation insulating film 5 is lowered except for the portion corresponding to the memory-cell side edge portion among the entire Y-direction length of select-gate line SGL1 (SGL2) of the select-gate transistor. As a result, it is possible to improve the properties of the select-gate transistor and maintain the properties (breakdown voltage) of the memory-cell transistor in the proximity of the select-gate transistor to a good level.

### Fourth Embodiment

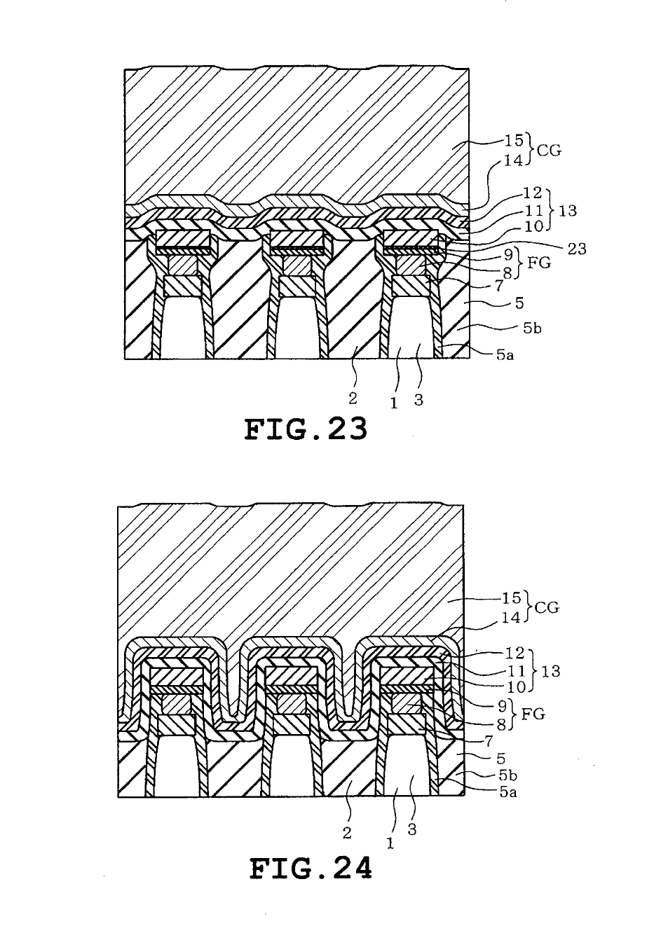

FIG. 23 illustrates a fourth embodiment. Structures identical to the first embodiment are identified with identical reference symbols. In the fourth embodiment, a metal layer 23 formed of for example ruthenium or iridium, etc., is formed (added) between insulating film 9 and first block film 10. The thickness of metal layer 23 is equal to or less than 1 nm for example. Metal layer 23 is formed so as to appear as metal dots bonded to insulating film 9.

Apart from those described above, the structures of the fourth embodiment are the same as the structures of the first embodiment. Thus, it is possible to obtain the operation and effect substantially identical to those of the first embodiment in the fourth embodiment as well. Especially in the fourth embodiment, metal layer 23 is formed between insulating film 9 and first block film 10. Thus, it is possible to improve the charge retainability of floating gate electrode FG by the increase in the band gap between floating gate electrode FG and IPD film 13 located between floating gate electrode FG and control gate electrode CG. As a result, it is possible to reduce the thickness of tunnel insulating film 7 and IPD film 13.

### Fifth Embodiment

FIG. 24 illustrates a fifth embodiment. Structures that are identical to the first embodiment are identified with identical reference symbols. In the fifth embodiment, the position of the upper portion of element isolation insulating film 5 of the select-gate transistor portion is further lowered. More specifically, as illustrated in FIG. 24, the position of the upper portion of element isolation insulating film 5 of the select-gate transistor portion is configured to be substantially the same with the position of the upper surface of active region 3 of silicon substrate 1 (the position of the under surface of the tunnel insulating film).

Apart from those described above, the structures of the fifth embodiment are the same as the structures of the first embodiment. Thus, it is possible to obtain the operation and effect substantially identical to those of the first embodiment in the fifth embodiment as well. Especially in the fifth embodiment, the position of the upper portion of element isolation insulating film 5 of the select-gate transistor portion is configured to be substantially the same with the position of the upper surface of active region 3 of silicon substrate 1. Thus, it is possible to improve the properties of the select-gate transistor more effectively.

In addition to the embodiments described above, the following configuration may be employed. Each of the embodiments, being applied to a NAND flash memory application, may be applied to other semiconductor devices provided with a flat-cell structure as well.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor device comprising:
a semiconductor substrate having an active region and an element isolation region, the active region being isolated by the element isolation region;
memory-cell transistors each being formed above the semiconductor substrate and having a gate electrode formed above the active region via a first insulating film, the gate electrode being formed of a stack including a floating gate electrode, an interelectrode insulating film, and a control gate electrode; and
select-gate transistors each being formed above the semiconductor substrate and having a gate electrode formed above the active region via the first insulating film, the gate electrode being formed of a stack including a floating gate electrode, an interelectrode insulating film, and a control gate electrode;
the element isolation region being formed of an element isolation trench and an element isolation insulating film filled in the element isolation trench,
a position of an upper surface of the element isolation insulating film located between the gate electrodes of the memory cell transistors being higher than a position of the upper surface of the floating gate electrode, and
a position of an upper surface of the element isolation insulating film located between the gate electrodes of the select-gate transistors being lower than a position of the upper surface of the floating gate electrode.

2. The semiconductor device according to claim 1, wherein the position of the upper surface of the element isolation insulating film located between the gate electrodes of the select-gate transistors is located at a vertical mid portion between an upper surface position and an under surface position of the floating gate electrode.

3. The semiconductor device according to claim 1, wherein the floating gate electrode comprises a stack of a silicon film formed of a polycrystalline silicon and an insulating film formed of a silicon nitride.

4. The semiconductor device according to claim 3, wherein the position of the upper surface of the element isolation insulating film located between the gate electrodes of the select-gate transistors is lower than a position of an upper surface of the silicon film.

5. The semiconductor device according to claim 3, further comprising a metal layer having a thickness of 1 nm or less above the insulating film.

6. The semiconductor device according to claim 1, wherein the interelectrode insulating film comprises a stack of a first block film formed of a hafnium oxide, a second block film formed of a silicon oxide, and a third block film formed of a hafnium oxide.

7. The semiconductor device according to claim 6, wherein the position of the upper surface of the element isolation insulating film located between the gate electrodes of the memory-cell transistors is higher than an under surface of the first block film.

8. The semiconductor device according to claim 1, wherein the element isolation region extends in a first direction, the control gate electrode extends in a second direction crossing the first direction, the first insulating film and the floating gate electrode being disposed above the active region, and the floating gate electrode being isolated in the first direction and the second direction.

9. The semiconductor device according to claim 8, wherein the interelectrode insulating film comprises a stack of a first block film formed of a hafnium oxide, a second block film formed of a silicon oxide, and a third block film formed of a hafnium oxide, and
wherein the first block film is isolated in the first direction and the second direction and the second block film and the third block film extend in the second direction.

10. The semiconductor device according to claim 8, wherein the position of a portion of the upper surface of the element isolation insulating film corresponding to a mid portion taken along the first direction of a select gate line of the select gate transistor is lower than a position of an upper surface of the floating gate electrode.

11. The semiconductor device according to claim 8, wherein the position of a portion of the upper surface of the element isolation insulating film corresponding to an entire region of a select gate line of the select gate transistor is lower than a position of an upper surface of the floating gate electrode.

12. The semiconductor device according to claim 8, wherein the position of a portion of the upper surface of the element isolation insulating film located in an opposite side of a portion of a select gate line of the select gate transistor adjacent to the memory cell transistors is lower than a position of an upper surface of the floating gate electrode.

13. A method of manufacturing a semiconductor device comprising:
forming a first insulating film above a semiconductor substrate;
forming a floating gate electrode above the first insulating film;
forming a first block film of an interelectrode insulating film above the floating gate electrode;
forming an element isolation trench into the first block film, the floating gate electrode, the first insulating film, and the silicon substrate;
filling an insulating film into the element isolation trench;
lowering a position of an upper surface of an element isolation insulating film located between gate electrodes of select-gate transistors by a first etching;
lowering a position of an upper surface of an element isolation insulating film located between gate electrodes of memory-cell transistors and further lowering the position of the upper surface of the element isolation insulating film located between the gate electrodes of the select-gate transistors by a second etching;
stacking a second block film of the interelectrode insulating film and thereafter a third block film of the interelectrode insulating film; and
forming a control gate electrode above the interelectrode insulating film.

14. The method of manufacturing a semiconductor device according to claim 13, wherein the first etching renders the position of the upper surface of the element isolation insulating film located between the gate electrodes of the select-gate transistors to be higher than a position of an upper surface of the floating gate electrode.

15. The method of manufacturing a semiconductor device according to claim 14, wherein the second etching renders the position of the upper surface of the element isolation insulating film located between the gate electrodes of the memory-cell transistors to be higher than the position of the upper surface of the floating gate electrode, and renders the position of the upper surface of the element isolation insulating film located between the gate electrodes of the select-gate transistors to be lower than the position of the upper surface of the floating gate electrode.

16. The method of manufacturing a semiconductor device according to claim 13, wherein forming the floating gate electrode stacks a silicon film formed of a polycrystalline silicon and thereafter an insulating film formed of a silicon nitride, and wherein the second etching step renders the position of the upper surface of the element isolation insulating film located between the gate electrodes of the memory-cell transistors to be higher than the position of the upper surface of the floating gate electrode, and renders the position of the upper surface of the element isolation insulating film located between the gate electrodes of the select-gate transistors to be lower than a position of an upper surface of the silicon film.

17. The method of manufacturing a semiconductor device according to claim 16 further comprising forming a metal layer having a thickness of 1 nm or less above the insulating film.

18. The method of manufacturing a semiconductor device according to claim 14, wherein the second etching renders the position of the upper surface of the element isolation insulating film located between the gate electrodes of the memory-cell transistors to be higher than the position of the upper surface of the floating gate electrode, and renders the position of the upper surface of the element isolation insulating film located between the gate electrodes of the select-gate transistors to be the same as a position of an under surface of the first insulating film.

19. The method of manufacturing a semiconductor device according to claim 13, wherein the first insulating film is formed of a silicon oxide.

20. The method of manufacturing a semiconductor device according to claim 13, wherein the first block film is formed of a hafnium oxide, the second block film is formed of a silicon oxide, and the third block film is formed of a hafnium oxide.
